(19) United States
(12) Patent Application Publication
(10) Pub. No.: US 2010/0081097 A1
(43) Pub. Date: Apr. 1, 2010

(54) SUBSTRATE PROCESSING APPARATUS

(75) Inventors: Koji Kaneyama, Kamigyo-ku (JP); Kazuhito Shigemori, Kamigyo-ku (JP); Akiko Harumoto, Kamigyo-ku (JP); Tadashi Miyagi, Kamigyo-ku (JP)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Sokudo Co., Ltd., Shimogyo-ku (JP)

(21) Appl. No.: 12/636,648

(22) Filed: Dec. 11, 2009

Related U.S. Application Data
(62) Division of application No. 11/474,614, filed on Jun. 21, 2006.

(30) Foreign Application Priority Data
Jun. 24, 2005 (JP) 2005-185763

(51) Int. Cl. G03F 7/20

(52) U.S. Cl. 430/422

(57) ABSTRACT

A substrate processing apparatus comprises an indexer block, an anti-reflection film processing block, a resist film processing block, a development processing block, a resist cover film processing block, a resist cover film removal block, a cleaning/drying processing block and an interface block. These blocks are arranged in the substrate processing apparatus in the above order. An exposure device is arranged adjacent to the interface block of the substrate processing apparatus. A hydrophobic processing unit is arranged in the resist cover film processing block and applies hydrophobic processing to the substrate before exposure processing.

### CROSS-REFERENCES TO RELATED APPLICATIONS

This application is a division of U.S. patent application Ser. No. 11/474,614, filed Jun. 21, 2006, which claims priority to Japanese Patent Application No. 2005-185763, filed Jun. 24, 2005. The disclosures of Ser. No. 11/474,614 and JP 2005-185763 are hereby incorporated by reference in their entirety for all purposes.

### FIELD OF THE INVENTION

The present invention relates to a substrate processing apparatus for applying processing to substrates.

### BACKGROUND OF THE INVENTION

A substrate processing apparatus is used to apply a variety of processing to substrates such as semiconductor substrates, substrates for use in liquid crystal displays, plasma displays, optical disks, magnetic disks, magneto-optical disks, photomasks, and other substrates.

Such a substrate processing apparatus typically applies a plurality of successive processing to a single substrate. The substrate processing apparatus as described in JP 2003-324139 A comprises an indexer block, an anti-reflection film processing block, a resist film processing block, a development processing block, and an interface block. An exposure device is arranged adjacent to the interface block as an external device separate from the substrate processing apparatus.

In the above-described substrate processing apparatus, a substrate is carried from the indexer block into the anti-reflection film processing block and the resist film processing block, where the formation of an anti-reflection film and resist film coating processing are applied to the substrate. The substrate is then transported to the exposure device through the interface block. After exposure processing has been applied to the resist film on the substrate by the exposure device, the substrate is transported to the development processing block through the interface block. In the development processing block, development processing is applied to the resist film on the substrate to form a resist pattern thereon, and the substrate is subsequently carried into the indexer block.

With recent improvements in the density and integration of devices, making finer resist patterns have become very important. Conventional exposure devices typically perform exposure processing by providing reduction projection of a reticle pattern on a substrate through a projection lens. With such conventional exposure devices, however, the line width of an exposure pattern is determined by the wavelength of the light source of an exposure device, thus making it impossible to make a resist pattern finer than that.

For this reason, a liquid immersion method is suggested as a projection exposure method allowing for finer exposure patterns (refer to, e.g., WO99/49504 pamphlet). In the projection exposure device according to the WO99/49504 pamphlet, a liquid is filled between a projection optical system and a substrate, resulting in a shorter wavelength of exposure light on a surface of the substrate. This allows for a finer exposure pattern.

However, in the projection exposure device according to the aforementioned WO99/49504 pamphlet, exposure processing is performed with the substrate and the liquid being in contact with each other. Accordingly, the liquid may possibly soak into the resist film on the substrate.

This causes pattern defects on the substrate and decreases yield by thermal and development processing on the soaked resist film after exposure processing.

### SUMMARY OF THE INVENTION

It is an object of the invention to provide a substrate processing apparatus capable of preventing pattern defects caused by liquid soaking into a film on a substrate during exposure.

(1) A substrate processing apparatus according to one aspect of the invention that is arranged adjacent to an exposure device includes a processing section for applying processing to a substrate, and an interface that is provided adjacent to an end of the processing section for exchanging the substrate between the processing section and the exposure device, wherein the processing section includes a photosensitive film formation unit that forms a photosensitive film made of a photosensitive material on the substrate before exposure processing by the exposure device, and a hydrophobic processing unit that applies hydrophobic processing to the substrate after formation of the photosensitive film by the photosensitive film formation unit and before exposure processing by the exposure device.

The substrate processing apparatus is arranged adjacent to the exposure device. In the substrate processing apparatus, the predetermined processing is applied to the substrate by the processing section and then the substrate is exchanged between the processing section and the exposure device by the interface arranged adjacent to the end of the processing section.

In the processing section, a photosensitive film is formed on the substrate by the photosensitive film formation unit and the hydrophobic processing is applied to the substrate with the photosensitive film formed thereon by the hydrophobic processing unit. The exposure processing is applied to the hydrophobic processed substrate by the exposure device.

Since the hydrophobic processing is applied to the substrate by the hydrophobic processing unit before the exposure processing, a liquid is prevented from soaking into the film on the substrate during the exposure processing in the exposure device. As a result, the generation of pattern defects on the substrate and a decrease in yield can be prevented.

(2) The hydrophobic processing unit may supply a hydrophobic material to the substrate. This allows the hydrophobic material to adhere onto the substrate and thus enhances hydrophobicity of the substrate, thereby preventing a liquid from soaking into the film on the substrate during the exposure processing by the exposure device.

(3) The hydrophobic processing unit may supply the hydrophobic material to the substrate in a gaseous state. In this case, the influence on the photosensitive material on the substrate is relatively small, as compared with that in a case where a liquid hydrophobic material is used. This prevents the photosensitivity of the photosensitive material from deteriorating.

(4) The hydrophobic processing unit may include a vaporizer that vaporizes the hydrophobic material, and a hydrophobic material supply device that supplies the hydrophobic material vaporized in the vaporizer to the substrate. In this case, the liquid hydrophobic material is vaporized in the vaporizer, and then the vaporized hydrophobic material is supplied to the substrate in the hydrophobic material supply device. This allows the hydrophobic material to be supplied to the substrate in a gaseous state.

(5) The hydrophobic processing unit may further include a current plate having a plurality of holes, and the hydrophobic material may be supplied to the substrate through the plurality of holes of the current plate.

This causes the hydrophobic material to spread uniformly on the substrate. Therefore, the hydrophobic processing is applied uniformly onto the surface of the substrate.

(6) The hydrophobic processing unit may further include a temperature control device that controls the temperature of the substrate mounted in the hydrophobic material supply device.

In this case, the temperature of the substrate can be controlled by the temperature control device when the hydrophobic processing is performed. This enables the hydrophobic processing to be effectively performed at the most appropriate temperature for the hydrophobic material to adhere to the substrate.

(7) The hydrophobic processing unit may control the temperature of the substrate mounted in the hydrophobic material supply device within the range of 23 to 150° C. This causes the hydrophobic material to reliably adhere onto the substrate without decreasing the photosensitivity of the photosensitive film.

(8) The hydrophobic material may include hexamethyldisilazane. In this case, the hexamethyldisilazane adheres onto the substrate and thus the hydrophobicity of the substrate is improved.

(9) The hydrophobic processing unit may apply hydrophobic processing to the photosensitive film formed on the substrate by the photosensitive film formation unit.

This prevents liquid from soaking into the photosensitive film on the substrate when the exposure processing is performed in the exposure device. This avoids generation of pattern defects on the substrate and a decrease in yield.

(10) The processing section may further include a protective film formation unit that forms a protective film for protecting the photosensitive film, and the hydrophobic processing unit may apply hydrophobic processing to the protective film formed by the protective film formation unit.

In this case, even when the exposure processing is performed in the exposure device with the substrate in contact with liquid, the component of the photosensitive material is prevented from being eluted into the liquid and the liquid is prevented from soaking into the photosensitive film and the protective film on the substrate. This avoids the generation of pattern defects on the substrate and the decrease in yield.

(11) The processing section may further include a removal unit that removes the protective film after the exposure processing by the exposure device. This ensures removal of the protective film formed on the photosensitive film.

(12) The processing section may include a drying processing unit that applies drying processing to the substrate after the exposure processing by the exposure device, the drying processing unit may be arranged adjacent to the interface, the interface may include a transport unit that transports the substrate between the processing section and the exposure device, and the transport unit may transport the substrate after the exposure processing from the exposure device to the drying processing unit.

In this case, in the interface, the substrate before the exposure processing is transported by the transport unit to the exposure device, while the substrate after the exposure processing is transported by the transport unit from the exposure device to the drying processing unit.

In the drying processing unit, drying processing is applied to the substrate. After that, in the interface, the substrate dried by the drying processing unit is received by the transport unit.

This prevents the liquid adhering to the substrate during the exposure processing by the exposure device from dropping in the substrate processing apparatus. As a result, operating troubles such as abnormalities in the electrical system of the substrate processing apparatus can be prevented.

In addition, the drying processing is applied to the substrate after the exposure processing, thereby preventing particles and the like in the atmosphere from adhering to the substrate after the exposure processing, which prevents the substrate from being contaminated.

In addition, as it is possible to prevent the substrate with liquid adhering from being transported in the substrate processing apparatus, which prevents the liquid adhering to the substrate during the exposure processing from influencing the atmosphere. This makes it easy to control temperature and humidity in the substrate processing apparatus.

It is also possible to prevent the liquid adhering to the substrate during the exposure processing from adhering to other substrates before exposure processing in the substrate processing apparatus. Therefore, since particles and the like in the atmosphere are prevented from adhering to other substrates before the exposure processing, degradation of resolution performance can be prevented and contamination in the exposure device can be reliably prevented.

As a result of these, processing defects can be certainly prevented.

(13) The transport unit may include first and second holders for holding the substrate, and the transport unit may hold the substrate with the first holder when transporting the substrate before the exposure processing by the exposure device and when transporting the substrate after the drying processing by the drying processing unit, and the transport unit may hold the substrate with the second holder when transporting the substrate after the exposure processing by the exposure device from the exposure device to the drying processing unit.

In this case, the substrate before the exposure processing is held with the first holder and transferred to the exposure device in the interface.

Also, the substrate after the exposure processing is held with the second holder and transported from the exposure device to the drying processing unit.

In addition, the substrate after the drying processing by the drying processing unit is held with the first holder and received from the drying processing unit.

That is to say, the second holder is used for transporting the substrate with liquid adhering during the exposure processing and the first holder is used for transporting the substrates without liquid before the exposure processing and after the drying processing by the drying processing unit. Accordingly, the liquid can be prevented from adhering to the first holder.

This can prevent liquid from adhering to the substrates before the exposure processing and after the drying processing by the drying processing unit. As a result, it is possible to reliably prevent particles and the like in the atmosphere from adhering to the substrates after the exposure processing and after the drying processing by the drying processing unit.

(14) The second holder may be provided below the first holder. In this case, even if liquid drops from the second holder and the substrate supported thereby, the liquid is prevented from adhering to the first holder and the substrate supported thereby. This makes it possible to reliably prevent particles and the like from adhering to the substrate before the exposure processing.

(15) The processing section may include a development processing unit that applies development processing to the substrate. In this case, the development processing is applied to the substrate by the development processing unit.

(16) The processing section may further include an anti-reflection film formation unit that forms an anti-reflection film on the substrate before forming the photosensitive film by the photosensitive film formation unit. In this case, since the anti-reflection film is formed on the substrate, it is possible to reduce potential standing waves and halation generated during the exposure processing. Consequently, it is possible to prevent the generation of pattern defects on the substrate and the decrease in yield.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic plan view of a substrate processing apparatus according to an embodiment of the invention;

FIG. 2 is a side view of the substrate processing apparatus in FIG. 1 that is seen from the +X direction;

FIG. 3 is a side view of the substrate processing apparatus in FIG. 1 that is seen from the −X direction;

FIG. 4 is a sectional view for use in illustrating the configuration of a hydrophobic processing unit;

FIG. 5 is a diagram for use in illustrating the configuration of a cleaning/drying processing unit;

FIG. 6 is a diagram for use in illustrating the operation of the cleaning/drying processing unit;

FIG. 7 is a diagram for use in illustrating the configuration and the operation of an interface transport mechanism;

FIG. 8 is a schematic diagram showing an example of the nozzle integrated for cleaning processing and drying processing;

FIG. 9 is a schematic diagram showing another example of the nozzle for drying processing;

FIG. 10 is a diagram for use in illustrating a method of applying drying processing to the substrate using the nozzle for drying processing in FIG. 9;

FIG. 11 is a schematic diagram showing another example of the nozzle for drying processing;

FIG. 12 is a schematic diagram showing another example of the cleaning/drying processing unit; and

FIG. 13 is a diagram for use in illustrating a method of applying drying processing to the substrate using the cleaning/drying processing unit in FIG. 12.

### DETAILED DESCRIPTION OF THE INVENTION

A substrate processing apparatus according to an embodiment of the invention will be described with reference to the drawings. A substrate as used in the description below includes a semiconductor substrate, a substrate for a liquid crystal display, a substrate for a plasma display, a glass substrate for a photomask, a substrate for an optical disk, a substrate for a magnetic disk, a substrate for a magneto-optical disk, and a substrate for a photomask.

Also, the subsequent drawings are accompanied by the arrows that indicate X, Y, and Z directions perpendicular to one another for clarification of positions. The X and Y directions are perpendicular to each other in a horizontal plane, and the Z direction corresponds to the vertical direction. In each of the directions, the direction at which an arrow points is defined as + direction, and the opposite direction is defined as − direction. The rotation direction centered around the Z direction is defined as θ direction.

(1) Configuration of the Substrate Processing Apparatus

A substrate processing apparatus according to an embodiment of the invention will be described with reference to the drawings.

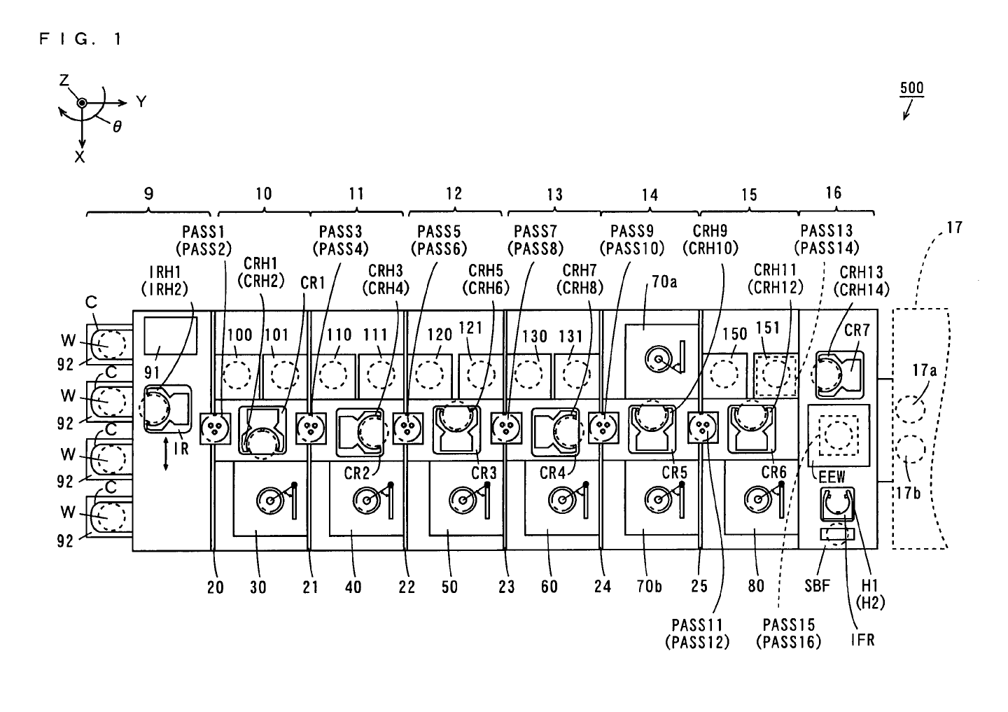

FIG. 1 is a schematic plan view of a substrate processing apparatus according to an embodiment of the invention.

As shown in FIG. 1, a substrate processing apparatus 500 includes an indexer block 9, an anti-reflection film processing block 10, a resist film processing block 11, a development processing block 12, a resist cover film processing block 13, a resist cover film removal block 14, a cleaning/drying processing block 15 and an interface block 16. In the substrate processing apparatus, these blocks are provided in the above order.

An exposure device 17 is arranged adjacent to the interface block 16 of the substrate processing apparatus 500. The exposure device 17 applies exposure processing to substrates W by a liquid immersion method.

The indexer block 9 includes a main controller (controller) 91 for controlling the operation of each block, a plurality of carrier platforms 92, and an indexer robot IR. The indexer robot IR has hands IRH1 and IRH2 provided one above the other for receiving and transferring the substrates W.

The anti-reflection film processing block 10 includes thermal processing groups 100, 101 for anti-reflection film, a coating processing group 30 for anti-reflection film, and a first central robot CR1. The coating processing group 30 is arranged opposite to the thermal processing groups 100, 101 with the first central robot CR1 therebetween. The first central robot CR1 has hands CRH1, CRH2 provided one above the other for receiving and transferring the substrates W.

A partition wall 20 is arranged between the indexer block 9 and the anti-reflection film processing block 10 for shielding an atmosphere. The partition wall 20 has substrate platforms PASS1, PASS2 provided closely one above the other for receiving and transferring the substrates W between the indexer block 9 and the anti-reflection film processing block 10. The upper substrate platform PASS1 is used in transferring the substrates W from the indexer block 9 to the anti-reflection film processing block 10, and the lower substrate platform PASS2 is used in transferring the substrates W from the anti-reflection film processing block 10 to the indexer block 9.

Each of the substrate platforms PASS1, PASS2 has an optical sensor (not shown) for detecting the presence or absence of a substrate W. This enables a determination to be made whether or not a substrate W is on the substrate platform PASS1, PASS2. In addition, each of the substrate platforms PASS1, PASS2 has a plurality of support pins secured thereto. Note that each of substrate platforms PASS3 to PASS16 mentioned below similarly has such an optical sensor and support pins.

The resist film processing block 11 includes thermal processing groups 110, 111 for resist film, a coating processing group 40 for resist film, and a second central robot CR2. The coating processing group 40 is arranged opposite to the thermal processing groups 110, 111 with the second central robot CR2 therebetween. The second central robot CR2 has hands CRH3, CRH4 provided one above the other for receiving and transferring the substrates W.

A partition wall 21 is arranged between the anti-reflection film processing block 10 and the resist film processing block 11 for shielding an atmosphere. The partition wall 21 has substrate platforms PASS3, PASS4 provided closely one above the other for receiving and transferring the substrates W between the anti-reflection film processing block 10 and the resist film processing block 11. The upper substrate platform PASS3 is used in transferring the substrates W from the anti-reflection film processing block 10 to the resist film processing block 11, and the lower substrate platform PASS4 is used in transferring the substrates W from the resist film processing block 11 to the anti-reflection film processing block 10.

The development processing block 12 includes thermal processing groups 120, 121 for development, a development processing group 50, and a third central robot CR3. The development processing group 50 is arranged opposite to the thermal processing groups 120, 121 with the third central robot CR3 therebetween. The third central robot CR3 has hands CRH5, CRH6 provided one above the other for receiving and transferring the substrates W.

A partition wall 22 is arranged between the resist film processing block 11 and the development processing block 12 for shielding an atmosphere. The partition wall 22 has substrate platforms PASS5, PASS6 provided closely one above the other for receiving and transferring the substrates W between the resist film processing block 11 and the development processing block 12. The upper substrate platform PASS5 is used in transferring the substrates W from the resist film processing block 11 to the development processing block 12, and the lower substrate platform PASS6 is used in transferring the substrates W from the development processing block 12 to the resist film processing block 11.

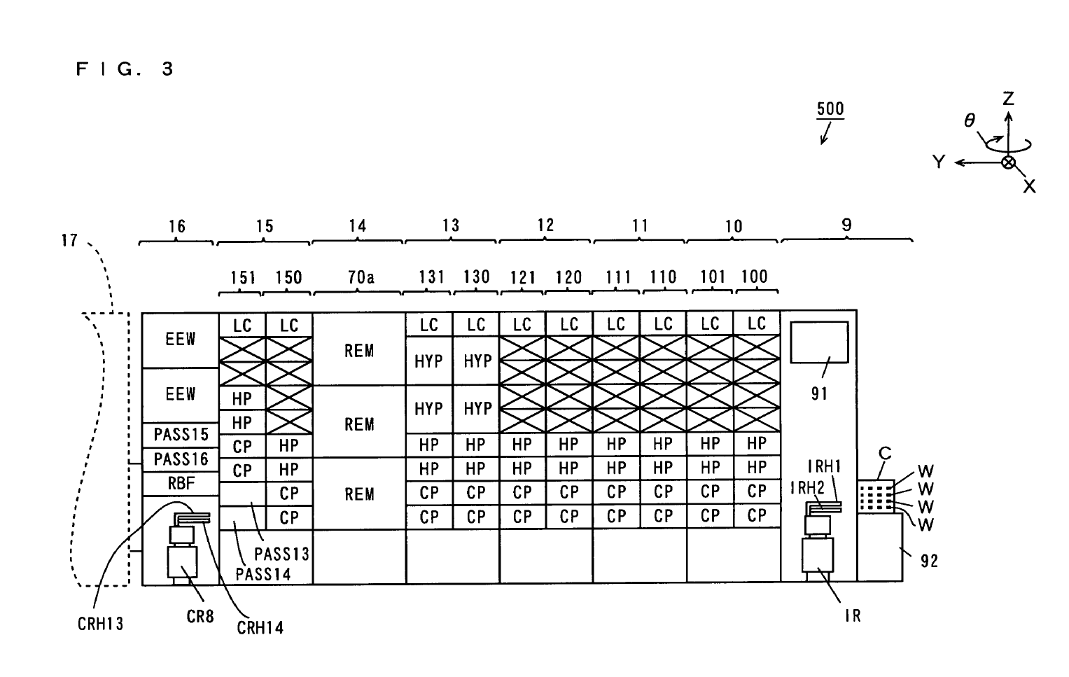

The resist cover film processing block 13 includes thermal processing groups 130, 131 for resist cover film, a coating processing group 60 for resist cover film, and a fourth central robot CR4. The thermal processing groups 130, 131 include hydrophobic processing units HYP shown in FIG. 3 below. Details of the hydrophobic processing units HYP will be described below. The coating processing group 60 is arranged opposite to the thermal processing groups 130, 131 with the fourth central robot CR4 therebetween. The fourth central robot CR4 has hands CRH7, CRH8 provided one above the other for receiving and transferring the substrates W.

A partition wall 23 is arranged between the development processing block 12 and the resist cover film processing block 13 for shielding an atmosphere. The partition wall 23 has substrate platforms PASS7, PASS8 provided closely one above the other for receiving and transferring the substrates W between the development processing block 12 and the resist cover film processing block 13. The upper substrate platform PASS7 is used in transferring the substrates W from the development processing block 12 to the resist cover film processing block 13, and the lower substrate platform PASS8 is used in transferring the substrates W from the resist cover film processing block 13 to the development processing block 12.

The resist cover film removal block 14 includes resist cover film removal processing groups 70a, 70b, and a fifth central robot CR5. The resist cover film removal processing groups 70a, 70b are arranged opposite to each other with the fifth central robot CR5 therebetween. The fifth central robot CR5 has hands CRH9, CRH10 provided one above the other for receiving and transferring the substrates W.

A partition wall 24 is arranged between the resist cover film processing block 13 and the resist cover film removal block 14 for shielding an atmosphere. The partition wall 24 has substrate platforms PASS9, PASS10 provided closely one above the other for receiving and transferring the substrates W between the resist cover film processing block 13 and the resist cover film removal block 14. The upper substrate platform PASS9 is used in transferring the substrates W from the resist cover film processing block 13 to the resist cover film removal block 14, and the lower substrate platform PASS10 is used in transferring the substrates W from the resist cover film removal block 14 to the resist cover film processing block 13.

The cleaning/drying processing block 15 includes thermal processing groups 150, 151 for post-exposure bake, a cleaning/drying processing group 80 and a sixth central robot CR6. The thermal processing group 151 is arranged adjacent to the interface block 16 and has substrate platforms PASS13, PASS14 as described below. The cleaning/drying processing group 80 is arranged opposite to the thermal processing groups 150,151 with the sixth central robot CR6 therebetween. The sixth central robot CR6 has hands CRH11, CRH12 provided one above the other for receiving and transferring the substrates W.

A partition wall 25 is arranged between the resist cover film removal block 14 and the cleaning/drying processing block 15 for shielding an atmosphere. The partition wall 25 has substrate platforms PASS11, PASS12 provided closely one above the other for receiving and transferring the substrates W between the resist cover film removal block 14 and the cleaning/drying processing block 15. The upper substrate platform PASS11 is used in transferring the substrates W from the resist cover film removal block 14 to the cleaning/drying processing block 15, and the lower substrate platform PASS12 is used in transferring the substrates W from the cleaning/drying processing block 15 to the resist cover film removal block 14.

The interface block 16 includes a seventh central robot CR7, a sending buffer unit SBF, an interface transport mechanism IFR and edge exposure units EEW. Substrate platforms PASS15, PASS16 mentioned below and a return buffer unit RBF are provided under the edge exposure units EEW. The seventh central robot CR7 has hands CRH13, CRH14 provided one above the other for receiving and transferring the substrates W, and the interface transport mechanism IFR has hands H1, H2 provided one above the other for receiving and transferring the substrates W.

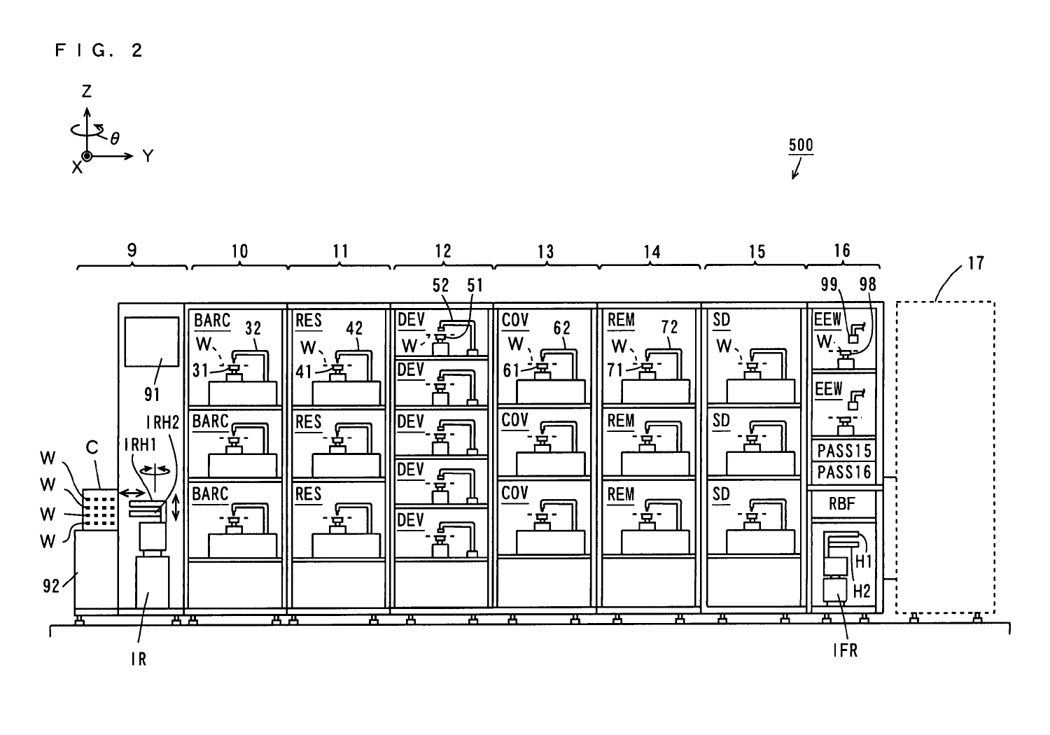

FIG. 2 is a side view of the substrate processing apparatus 500 in FIG. 1 that is seen from the +X direction.

The coating processing group 30 in the anti-reflection film processing block 10 (see FIG. 1) includes a vertical stack of three coating units BARC. Each of the coating units BARC includes a spin chuck 31 for rotating a substrate W while holding the substrate W in a horizontal attitude by suction, and a supply nozzle 32 for supplying coating liquid for anti-reflection film to the substrate W held on the spin chuck 31.

The coating processing group 40 in the resist film processing block 11 (see FIG. 1) includes a vertical stack of three coating units RES. Each of the coating units RES includes a spin chuck 41 for rotating a substrate W while holding the substrate W in a horizontal attitude by suction, and a supply nozzle 42 for supplying coating liquid for resist film to the substrate W held on the spin chuck 41.

The development processing group 50 in the development processing block 12 (see FIG. 1) includes a vertical stack of five development processing units DEV. Each of the development processing units DEV includes a spin chuck 51 for rotating a substrate W while holding the substrate W in a horizontal attitude by suction, and a supply nozzle 52 for supplying development liquid to the substrate W held on the spin chuck 51.

The coating processing group 60 in the resist cover film processing block 13 (see FIG. 1) includes a vertical stack of three coating units COV. Each of the coating units COV includes a spin chuck 61 for rotating a substrate W while holding the substrate W in a horizontal attitude by suction, and a supply nozzle 62 for supplying coating liquid for resist cover film to the substrate W held on the spin chuck 61. Materials having low affinity with resists and water (materials having low reactivity to resists and water) can be used as the coating liquid for resist cover film. For example, fluororesin may be used as the coating liquid. Each of the coating units COV forms the resist cover film on the resist film formed on the substrate W by applying the coating liquid onto the substrate W while rotating the substrate W.

The resist cover film removal processing group 70b in the resist cover film removal block 14 (see FIG. 1) has a vertical stack of three removal units REM. Each of the removal units REM includes a spin chuck 71 for rotating a substrate W while holding the substrate W in a horizontal attitude by suction, and a supply nozzle 72 for supplying stripping liquid (e.g. fluororesin) to the substrate W held on the spin chuck 71. Each removal unit REM removes the resist cover film formed on the substrate W by applying the stripping liquid onto the substrates W while rotating the substrate W.

Note that a method of removing the resist cover films in the removal units REM is not limited to the above examples. For example, the resist cover film may be removed by supplying the stripping liquid onto the substrate W while moving a slit nozzle above the substrate W.

The cleaning/drying processing group 80 in the cleaning/drying processing block 15 (see FIG. 1) has a vertical stack of three cleaning/drying processing units SD. Details of the cleaning/drying processing units SD will be described below.

The interface block 16 includes a vertical stack of the two edge exposure units EEW, the substrate platforms PASS15, PASS16 and the return buffers RBF, as well as the seventh central robot CR7 (see FIG. 1) and the interface transport mechanism IFR. Each of the edge exposure units EEW includes a spin chuck 98 for rotating a substrate W in a horizontal attitude by suction, and a light irradiator 99 for subjecting a peripheral portion of the substrate W held on the spin chuck 98 to exposure.

FIG. 3 is a side view of the substrate processing apparatus 500 in FIG. 1 that is seen from the −X direction.

In the anti-reflection film processing block 10, a thermal processing group 100 for anti-reflection film includes a vertical stack of two heating units (hot plates) HP and two cooling units (cooling plates) CP, and a thermal processing group 101 for anti-reflection film includes a vertical stack of two heating units HP and two cooling units CP. Each of the thermal processing groups 100, 101 also includes a local controller LC on top thereof for controlling the temperatures of the cooling units CP and the heating units HP.

In the resist film processing block 11, a thermal processing group 110 includes a vertical stack of two heating units HP and two cooling units CP, and the thermal processing group 111 includes a vertical stack of two heating units HP and two cooling units CP. Each of the thermal processing groups 110, 111 also includes a local controller LC on top thereof for controlling the temperatures of the cooling units CP and the heating units HP.

In the development processing block 12, a thermal processing group 120 includes a vertical stack of two heating units HP and two cooling units CP, and a thermal processing group 121 includes a vertical stack of two heating units HP and two cooling units CP. Each of the thermal processing groups 120, 121 also includes a local controller LC on top thereof for controlling the temperatures of the cooling units CP and the heating units HP.

In the resist cover film processing block 13, a thermal processing group 130 includes a vertical stack of two hydrophobic processing units HYP, two heating units HP and two cooling units CP, and the thermal processing group 131 includes a vertical stack of two hydrophobic processing units HYP, two heating units HP and two cooling units CP. Each of the thermal processing groups 130, 131 also includes a local controller LC on top thereof for controlling the temperatures of the cooling units CP and the heating units HP. Details of the hydrophobic processing units HYP will be described.

A resist cover film removal processing group 70a in the resist cover film removal block 14 includes a vertical stack of three removal units REM.

In the cleaning/drying processing block 15, a thermal processing group 150 for post-exposure bake includes a vertical stack of two heating units HP and two cooling units CP, and a thermal processing group 151 includes a vertical stack of two heating units HP, two cooling units CP, and substrate platforms PASS13, 14. Each of the thermal processing groups 150, 151 includes a local controller LC on top thereof for controlling the temperatures of the cooling units CP and the heating units HP.

Note that the number of coating units BARC, RES, COV, the hydrophobic processing units HYP, the cleaning/drying processing units SD, the removal units REM, the development units DEV, the heating units HP and the cooling units CP may be appropriately changed depending on the processing speed of each block.

(2) Operation of the Substrate Processing Apparatus

Next, the operation of the substrate processing apparatus 500 in this embodiment will be described with reference to FIGS. 1 to 3.

Carriers C for storing the substrates W in multiple stages are mounted on the carrier platforms 92, respectively, in the indexer block 9. The indexer robot IR takes out a substrate W yet to be processed that is stored in a carrier C using the upper hand IRH1. Then, the indexer robot IR moves in the ±X direction while rotating in the ±θ direction to transfer the unprocessed substrate W onto the substrate platform PASS1.

Although FOUPs (Front Opening Unified Pods) are adopted as the carriers C in this embodiment, SMIF (Standard Mechanical Inter Face) pods or OCs (Open Cassettes) that expose stored substrates W to outside air may also be used, for example. In addition, although linear-type transport robots that move their hands forward or backward by sliding them linearly to a substrate W are used as the indexer robot IR, the first central robot CR1 to the seventh central robot CR7, and the interface transport mechanism IFR, multi joint type transport robots that linearly move their hands forward and backward by moving their joints may also be used.

The substrate W that has been transferred onto the substrate platform PASS1 is received by the first central robot CR1 in the anti-reflection film processing block 10. The first central robot CR1 carries the substrate W into the coating processing group 30. The coating processing group 30 forms a coating of an anti-reflection film on the substrate W using a coating unit BARC, in order to reduce potential standing waves and halation that may be generated during exposure.

The first central robot CR1 subsequently takes out the substrate W after coating processing from the coating processing group 30, and carries the substrate W into the thermal processing group 100 or 101. Then, the first central robot CR1 takes out the thermally processed substrate W from the thermal processing groups 100 or 101, and transfers the substrate W onto the substrate platform PASS3.

The substrate W on the substrate platform PASS3 is received by the second central robot CR2 in the resist film processing block 11. The second central robot CR2 carries the substrate W into the coating processing group 40. In the coating processing group 40, a coating unit RES forms a coating of a resist film on the substrate W that is coated with the anti-reflection film.

After this, the second central robot CR2 takes out the substrate W after coating processing from the coating processing group 40, and carries the substrate W into the thermal processing group 110 or 111. Then, the second central robot CR2 takes out the thermally processed substrate W from the thermal processing group 110 or 111, and transfers the substrate W onto the substrate platform PASS5.

The substrate W on the substrate platform PASS5 is received by the third central robot CR3 in the development processing block 12. The third central robot CR3 transfers the substrate W onto the substrate platform PASS7.

The substrate W on the substrate platform PASS7 is received by the fourth central robot CR4 in the resist cover film processing block 13. The fourth central robot CR4 carries the substrate W into the coating processing group 60. In the coating processing group 60, a coating unit COV forms a coating of a resist cover film over the resist film as described above.

The fourth central robot CR4 then takes out the substrate W after coating processing from the coating processing group 60, and carries the substrate W into the thermal processing group 130 or 131. In the thermal processing group 130 or 131, after the substrate W is thermally processed by a heating unit HP and a cooling unit CP, the surface of the resist cover film is hydrophobized by a hydrophobic processing unit HYP. Details will be described below. The fourth central robot CR4 then takes out the substrate W after thermal processing and hydrophobic processing from the thermal processing group 130 or 131, and transfers the substrate W onto the substrate platform PASS9.

The substrate W on the substrate platform PASS9 is received by the fifth central robot CR5 in the resist cover film removal block 14. The fifth central robot CR5 transfers the substrate W onto the substrate platform PASS11.

The substrate W on the substrate platform PASS11 is received by the sixth central robot CR6 in the cleaning/drying processing block 15. The sixth central robot CR6 transfers the substrate W onto the substrate platform PASS13.

The substrate W on the substrate platform PASS13 is received by the seventh central robot CR7 in the interface block 16. The seventh central robot CR7 carries the substrate W into an edge exposure unit EEW. In the edge exposure unit EEW, the peripheral portion of the substrate W is subjected to exposure processing.

The seventh central robot CR7 then takes out the substrate W after exposure processing from the edge exposure unit EEW, and transfers the substrate W onto the substrate platform PASS15. The substrate W on the substrate platform PASS15 is carried into a substrate inlet 17a in the exposure device 17 (see FIG. 1) by the interface transport mechanism IFR. If the exposure device 17 cannot accept the substrate W, the substrate W is temporarily stored in the sending buffer unit SBF.

The substrate W after exposure processing in the exposure device 17 is taken out by the interface transport mechanism IFR from a substrate outlet 17b of the exposure device 17 (see FIG. 1) and carried into the cleaning/drying processing group 80 in the cleaning/drying processing block 15. In a cleaning/drying processing unit SD in the cleaning/drying processing group 80, the substrate W after exposure processing is subjected to cleaning and drying processing. Details will be described below.

After the substrate W after exposure processing is subjected to cleaning and drying processing in the cleaning/drying processing group 80, the interface transport mechanism IFR takes out the substrate W from the cleaning/drying processing group 80 and transfers the substrate W onto the substrate platform PASS16. Details of the operations of the interface transport mechanism IFR in the interface block 16 will be described below.

When cleaning and drying processing can not be applied temporarily in the cleaning/drying processing group 80 due to a failure or the like, the substrate W after exposure processing can be stored temporarily in the return buffer unit RBF in the interface block 16.

The substrate W on the substrate platform PASS16 is received by the seventh central robot CR7 in the interface block 16. The seventh central robot CR7 carries the substrate W into the thermal processing group 151 for post-exposure bake in the cleaning/drying processing block 15. In the thermal processing group 151 for post-exposure bake, post-exposure bake (PEB) is applied to the substrate W. Then, the seventh central robot CR7 takes out the substrate W from the thermal processing group 151 for post-exposure bake and transfers the substrate W onto the substrate platform PASS14.

Although baking processing after exposure is applied by the thermal processing group 151 for post-exposure bake in this embodiment, it is also possible to apply baking processing after exposure by the thermal processing group 150 for post-exposure bake.

The substrate W on the substrate platform PASS14 is received by the sixth central robot CR6 in the cleaning/drying processing block 15. The sixth central robot CR6 transfers the substrate W onto the substrate platform PASS12.

The substrate W on the substrate platform PASS12 is received by the fifth central robot CR5 in the resist cover film removal block 14. The fifth central robot CR5 carries the substrate W into the resist cover film removal processing group 70a or the resist cover film removal processing group 70b. The resist cover film on the substrate W is removed by a removal unit REM in the resist cover film removal processing groups 70a or 70b.

After that, the fifth central robot CR5 takes out the processed substrate W from the resist cover film removal processing group 70a or the resist cover film removal processing group 70a and transfers the substrate W onto the substrate platform PASS10.

The substrate W on the substrate platform PASS10 is received by the fourth central robot CR4 in the resist cover film processing block 13. The fourth central robot CR4 transfers the substrate W onto the substrate platform PASS8.

The substrate W on the substrate platform PASS8 is received by the third central robot CR3 in the development processing block 12. The third central robot CR3 carries the substrate W into the development processing group 50. In the development processing group 50, development processing is applied to the substrate W by a development processing unit DEV.

The third central robot CR3 then takes out the substrate W after development processing from the development processing group 50 and carries the substrate W into the thermal processing group 120 or 121 for development.

The third central robot CR3 subsequently takes out the substrate W after thermal processing from the thermal processing groups 120 or 121 for development and transfers the substrate W onto the substrate platform PASS6.

The substrate W on the substrate platform PASS6 is received by the second central robot CR2 in the resist film processing group 11. The second central robot CR2 transfers the substrate W onto the substrate platform PASS4.

The substrate W on the substrate platform PASS4 is received by the first central robot CR1 in the anti-reflection film processing block 10. The first central robot CR1 transfers the substrate W onto the substrate platform PASS2.

The substrate W on the substrate platform PASS2 is stored in a carrier C by the indexer robot IR in the indexer block 9.

(3) Hydrophobic Processing Unit HYP

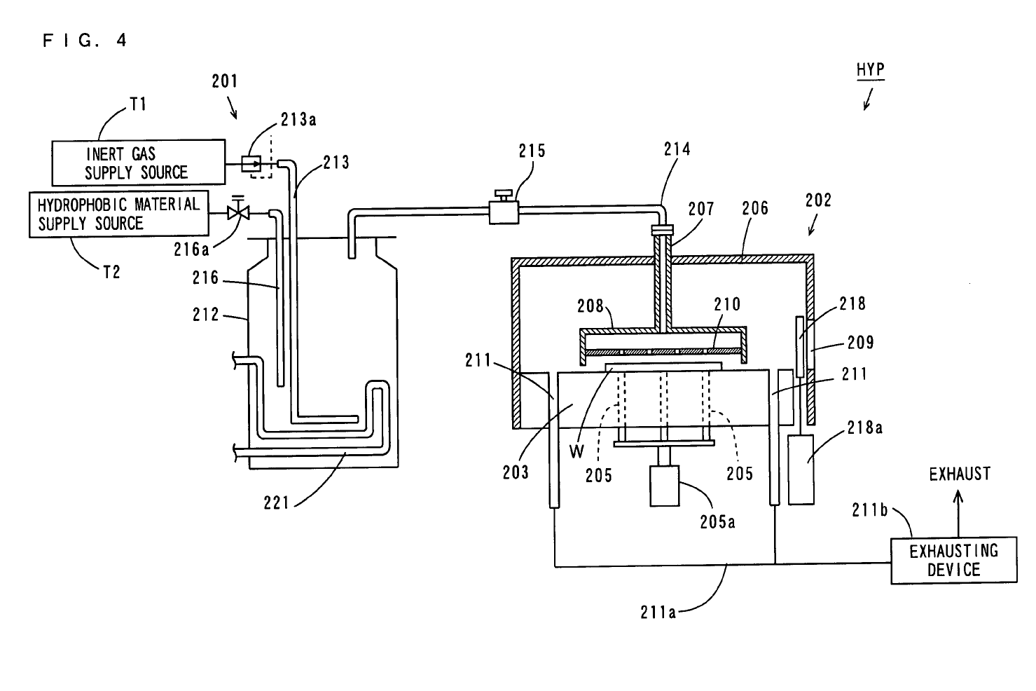

Now, the aforementioned hydrophobic processing unit HYP will be described in detail with reference to drawings. FIG. 4 is a cross-sectional diagram for use in illustrating a configuration of the hydrophobic processing unit HYP.

As shown in FIG. 4, the hydrophobic processing unit HYP includes a vaporization processing device 201 for vaporizing a liquid hydrophobic material, and a hydrophobic material supply device 202 for supplying a hydrophobic material vaporized in the vaporization processing device 201 to the substrate W.

The vaporization processing device 201 includes a liquid storage tank 212 for storing the hydrophobic material. The liquid storage tank 212 is connected to an inert gas supply source T1 through an inert gas pipe 213, and to a hydrophobic material supply source T2 through a hydrophobic material supply pipe 216. The inert gas supply pipe 213 is provided with a regulator 213a, and then an inert gas is supplied from the inert gas supply source T1 to the liquid storage tank 212 under a certain pressure. The hydrophobic material supply pipe 216 is provided with a valve 216a and a hydrophobic material is supplied from the hydrophobic material supply source T2 to the liquid storage tank 212 by opening the valve 216a.

A heat exchange coil 221 is provided at the lower portion in the liquid storage tank 212. With electric current supplied to the heat exchange coil 221, the temperature of the heat exchange coil 221 rises and the hydrophobic material in the liquid storage tank 212 is vaporized.

The hydrophobic material supply device 202 has a substrate platform plate 203. The substrate platform plate 203 heats the substrate W mounted on its top surface to a predetermined temperature. A plurality of lifting pins 205 are provided to go through the substrate platform plate 203 in the vertical direction. The lifting pins 205 are moved up and down by a lifting pins driving device 205a. In addition, an exhaust port 211 is provided so as to surround the periphery of the substrate platform plate 203. The exhaust port 211 is connected to an exhausting device 211b through a pipe 211a. An atmosphere over the substrate platform plate 203 is exhausted by the exhausting device 211b from the exhaust port 211 through the pipe 211a.

A cover 206 is provided over the substrate platform plate 203. A tubular supporting member 207 is provided so as to move up and down through the center of the cover 206 in the vertical direction. A pipe 214 is connected to the upper end of the supporting member 207 so as to be communicated with the liquid storage tank 212 in the vaporization processing device 201. The hydrophobic material vaporized in the vaporization processing device 201 is fed through the pipe 214 in the supporting member 207 in the hydrophobic material supply device 202. The pipe 214 is provided with a valve 215, and the flow rate of the hydrophobic material fed from the vaporization processing device 201 to the hydrophobic material supply device 202 is controlled by opening and closing the valve 215.

A chamber 208 is provided at the lower end of the supporting member 207. The inside of the supporting member 207 is communicated with the inner space of the chamber 208. A current plate 210 having a plurality of holes in its whole plane is provided inside the chamber 208. The chamber 208 is arranged above so as to move up and down the substrate platform plate 203 with the current plate 210 opposite to the substrate W.

A side of the cover 206 has the carry-in/out opening 209 through which is carried in and out the substrate W. A shutter 218 is provided to close the carry-in/out opening 209 inside the cover 206. The shutter 218 moves up and down by a shutter driving device 218a to open and close the carry-in/out opening 209.

Next, the operation of the hydrophobic processing unit HYP with the aforementioned configuration is described. Note that the operation of each constituent element in the hydrophobic processing unit HYP described below is controlled by a main controller 91 in FIG. 1.

First, the supporting member 207 and the chamber 208 are moved up, and the lifting pins 205 are moved up by the lifting driving device 205a. The shutter 218 is moved down by the shutter driving device 218a so that the carry-in/out opening 209 is opened. In this state, the substrate W is mounted onto the lifting pins 205 inside the cover 206 by the fourth central robot CR4 in FIG. 4. Then, the lifting pins 205 are moved down by the lifting driving device 205a, so that the substrate W on the lifting pins 205 is supported on the top surface of the substrate platform plate 203. Also, the shutter 218 is moved up by the shutter driving device 218a, so that the carry-in/out opening 209 is closed.

The supporting member 207 and the chamber 208 are subsequently moved down. In this state, the substrate W on the substrate platform plate 203 is heated up to a predetermined temperature. Preferably, the temperature of the substrate W is controlled by the substrate platform plate 203 within the range of 23 to 150° C.

Next, the vaporized hydrophobic material is fed from the liquid storage tank 212 through the pipe 214 into the supporting member 207 in the hydrophobic material supply device 202 and supplied to the substrate W through a plurality of fine holes of the current plate 210. Thus, the hydrophobic processing is applied to the surface of the resist cover film on the substrate W. The hydrophobic material inside the cover 206 is exhausted by the exhausting device 211b from the exhaust port 211 through the pipe 211a.

After the processing is finished, the supporting member 207 and the chamber 208 is moved up. Then, the lifting pins 205 are moved up by the lifting driving device 205a, so that the substrate W is lifted up by the lifting pins 205. The shutter 218 is moved down by the shutter driving device 218a and the carry-in/out opening 209 of the cover 206 is opened. Then, the fourth central robot CR4 in FIG. 1 carries the substrate W out of the hydrophobic processing unit HYP.

As the hydrophobic material supplied to the substrate W, materials which do not degrade the characteristics of the resist film and the resist cover film and prevent liquid from soaking into the resist film and the resist cover film are used. For example, HMDS (hexametyldisilazane) or low-molecular materials or the like can be used. Nitrogen gas (N₂ gas), for example, can be used as an inert gas to be supplied by the vaporization processing device 201. Other gases such as argon gas (Ar gas) can be also used as an inert gas.

(4) Cleaning/Drying Processing Unit

Now, the aforementioned cleaning/drying processing unit SD will be described in detail with reference to drawings.

(4-a) Configuration of Cleaning/Drying Processing Unit

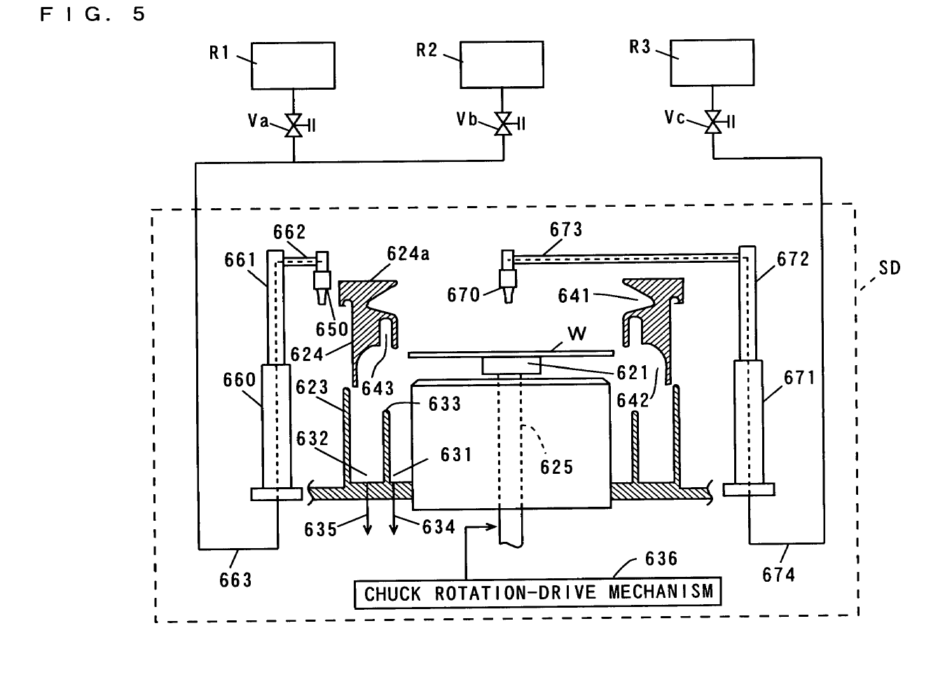

The configuration of a cleaning/drying processing unit SD is described. FIG. 5 is a diagram for use in illustrating the configuration of the cleaning/drying processing unit SD.

As shown in FIG. 5, the cleaning/drying unit SD includes a spin chuck 621 for rotating a substrate W about the vertical rotation axis passing through the center of the substrate W while horizontally holding the substrate W.

The spin chuck 621 is secured to an upper end of a rotation shaft 625, which is rotated via a chuck rotation-drive mechanism 636. An air suction passage (not shown) is formed in the spin chuck 621. With the substrate W being mounted on the spin chuck 621, air inside the air suction passage is discharged, so that a lower surface of the substrate W is sucked onto the spin chuck 621 by vacuum, and the substrate W can be held in a horizontal attitude.

A first rotation motor 660 is arranged outside the spin chuck 621. The first rotation motor 660 is connected to a first rotation shaft 661. The first rotation shaft 661 is coupled to a first arm 662, which extends in the horizontal direction, and whose end is provided with a nozzle 650 for cleaning processing.

The first rotation shaft 661 is rotated by the first rotation motor 660, so that the first arm 662 swings. This causes the nozzle 650 to move above the substrate W held on the spin chuck 621.

A supply pipe 663 for cleaning processing is arranged so as to pass through the inside of the first rotation motor 660, the first rotation shaft 661, and the first arm 662. The supply pipe 663 is connected to a cleaning liquid supply source R1 and a rinse liquid supply source R2 through a valve Va and a valve Vb, respectively. By controlling the opening and closing of the valves Va, Vb, it is possible to select a processing liquid supplied to the supply pipe 663 and adjust the amount of the processing liquid. In the configuration of FIG. 5, when the valve Va is opened, cleaning liquid is supplied to the supply pipe 663, and when the valve Vb is opened, rinse liquid is supplied to the supply pipe 663.

The cleaning liquid or the rinse liquid is supplied to the nozzle 650 through the supply pipe 663 from the cleaning liquid supply source R1 or the rinse liquid supply source R2. The cleaning liquid or the rinse liquid is thus supplied to a surface of the substrate W. Examples of the cleaning liquid may include pure water, a pure water solution containing a complex (ionized), or a fluorine-based chemical solution. Examples of the rinse liquid may include pure water, carbonated water, hydrogen water, electrolytic ionic water, and HFE (hydrofluoroether).

A second rotation motor 671 is arranged outside the spin chuck 621. The second rotation motor 671 is connected to a second rotation shaft 672. The second rotation shaft 672 is coupled to a second arm 673, that extends in the horizontal direction, and whose end is provided with a nozzle 670 for drying processing.

The second rotation shaft 672 is rotated by the second rotation motor 671, so that the second arm 673 swings. This causes the nozzle 670 to move above the substrate W held on the spin chuck 621.

A supply pipe 674 for drying processing is arranged so as to pass through the inside of the second rotation motor 671, the second rotation shaft 672, and the second arm 673. The supply pipe 674 is connected to an inert gas supply source R3 through a valve Vc. By controlling the opening and closing of the valve Vc, it is possible to adjust the amount of the inert gas supplied to the supply pipe 674.

The inert gas is supplied to the nozzle 670 through the supply pipe 674 from the inert gas supply source R3. The inert gas is thus supplied to the surface of the substrate W. Nitrogen gas (N₂), for example, may be used as the inert gas.

When supplying the cleaning liquid or the rinse liquid onto the surface of the substrate W, the nozzle 650 is positioned above the substrate. When supplying the inert gas onto the surface of the substrate W, the nozzle 650 is retracted to a predetermined position.

When supplying the cleaning liquid or the rinse liquid onto the surface of the substrate W, the nozzle 670 is retracted to a predetermined position. When supplying the inert gas onto the surface of the substrate W, the nozzle 670 is positioned above the substrate W.

The substrate W held on the spin chuck 621 is housed in a processing cup 623. A cylindrical partition wall 633 is provided inside the processing cup 623. A discharge space 631 is formed so as to surround the spin chuck 621 for discharging the processing liquid (i.e., cleaning liquid or rinse liquid) used in processing the substrate W. Also, a liquid recovery space 632 is formed between the processing cup 623 and the partition wall 633, so as to surround the discharge space 631, for recovering the processing liquid used in processing the substrate W.

The discharge space 631 is connected with a discharge pipe 634 for directing the processing liquid to a liquid discharge processing device (not shown), while the liquid recovery space 632 is connected with a recovery pipe 635 for directing the processing liquid to a recovery processing device (not shown).

A guard 624 is provided above the processing cup 623 for preventing the processing liquid on the substrate W from splashing outward. The guard 624 is configured to be rotation-symmetric with respect to the rotation shaft 625. An annular-shaped liquid discharge guide groove 641 with a V-shaped cross section is formed inwardly of an upper end portion of the guard 624.

Also, a liquid recovery guide 642 having an inclined surface that inclines down outwardly is formed inwardly of a lower portion of the guard 624. A partition wall housing groove 643 for receiving the partition wall 633 in the processing cup 623 is formed in the vicinity of the upper end of the liquid recovery guide 642.

This guard 624 is provided with a guard lifting mechanism (not shown) composed of a ball-screw mechanism or the like. The guard lifting mechanism lifts and lowers the guard 624 between a recovery position in which the liquid recovery guide 642 is positioned opposite to outer edges of the substrate W held on the spin chuck 621 and a discharge position in which the liquid discharge guide groove 641 is positioned opposite to the outer edges of the substrate W held on the spin chuck 621. When the guard 624 is in the recovery position (i.e., the position of the guard shown in FIG. 5), the processing liquid splashed out from the substrate W is directed by the liquid recovery guide 642 to the liquid recovery space 632, and then recovered through the recovery pipe 635. On the other hand, when the guard 624 is in the discharge position, the processing liquid splashed out from the substrate W is directed by the liquid discharge guide groove 641 to the discharge space 631, and then discharged through the discharge pipe 634. With such a configuration, discharge and recovery of the processing liquid is performed.

(4-b) Operation of Cleaning/Drying Processing Unit

The processing operation of the cleaning/drying processing unit SD having the aforementioned configuration is next described. Note that the operation of each component in the cleaning/drying processing unit SD described below is controlled by the main controller (controller) 91 in FIG. 1.

When the substrate W is initially carried into the cleaning/drying processing unit SD, the guard 624 is lowered, and the interface transport mechanism IFR in FIG. 1 places the substrate W onto the spin chuck 621. The substrate W on the spin chuck 621 is held by suction.

Next, the guard 624 moves to the aforementioned discharge position, and the nozzle 650 moves above the center of the substrate W. Then, the rotation shaft 625 rotates, causing the substrate W held on the spin chuck 621 to rotate. After this, the cleaning liquid is discharged onto the top surface of the substrate W from the nozzle 650. The substrate W is thus cleaned.

In the cleaning/drying processing group 80a, the part of the component of the resist cover film on the substrate W is eluted in the cleaning liquid. During the cleaning of the substrate W, the substrate W is rotated as the cleaning liquid is supplied onto the substrate W. This causes the cleaning liquid on the substrate W to constantly move toward a peripheral portion of the substrate W by the centrifugal force, and splash away. It is therefore possible to prevent the component of the resist cover film eluted in the cleaning liquid from remaining on the substrate W. Note that the aforementioned resist cover film component may be eluted with pure water being poured onto the substrate W and kept thereon for a certain period. The supply of the cleaning liquid onto the substrate W may also be executed by a soft spray method using a two-fluid nozzle.

After the elapse of a predetermined time, the supply of the cleaning liquid is stopped, and the rinse liquid is discharged from the nozzle 650. The cleaning liquid on the substrate W is thus cleaned away.

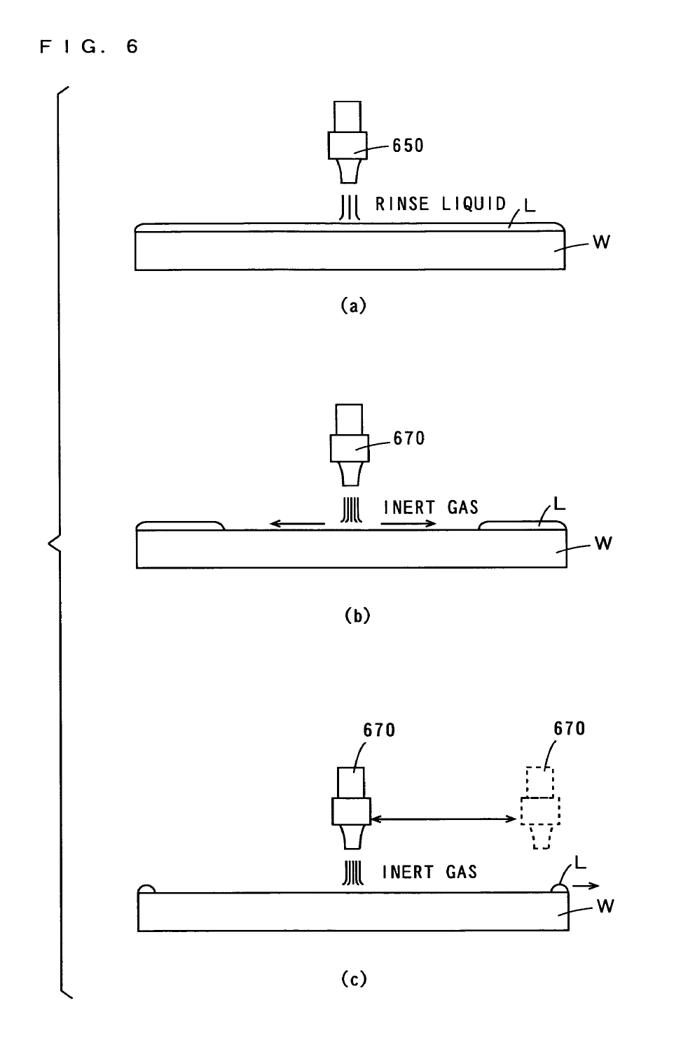

After the elapse of another predetermined time, the rotation speed of the rotation shaft 625 decreases. This reduces the amount of the rinse liquid that is shaken off by the rotation of the substrate W, resulting in the formation of a liquid layer L of the rinse liquid over the entire surface of the substrate W, as shown in FIG. 6 (a). Alternatively, the rotation of the rotation shaft 625 may be stopped to form the liquid layer L over the entire surface of the substrate W.

The supply of the rinse liquid is subsequently stopped, and the nozzle 650 retracts to the predetermined position while the nozzle 670 moves above the center of the substrate W. The inert gas is subsequently discharged from the nozzle 670. This causes the rinse liquid around the center of the substrate W to move toward the peripheral portion of the substrate W, leaving the liquid layer L only on the peripheral portion, as shown in FIG. 6 (b).

Next, as the number of revolutions of the rotation shaft 625 (see FIG. 5) increases, the nozzle 670 gradually moves from above the center of the substrate W to above the peripheral portion thereof, as shown in FIG. 6 (c). This causes a great centrifugal force acting on the liquid layer L on the substrate W while allowing the inert gas to be sprayed toward the entire surface of the substrate W, thereby ensuring the removal of the liquid layer L on the substrate W. As a result, the substrate W can be reliably dried.

Then, the supply of the inert gas is stopped, and the nozzle 670 retracts to the predetermined position while the rotation of the rotation shaft 625 is stopped. After this, the guard 624 is lowered, and the interface transport mechanism IFR in FIG. 1 carries the substrate W out of the cleaning/drying processing unit SD. The processing operation of the cleaning/drying processing unit SD is thus completed. It is preferred that the position of the guard 624 during cleaning and drying processing is suitably changed according to the necessity of the recovery or discharge of the processing liquid.

According to the above embodiment, although the configuration of sharing the nozzle 650 for the supply of both the cleaning liquid and the rinse liquid is adopted to allow either of the cleaning liquid and the rinse liquid to be supplied from the nozzle 650, the configuration of using the nozzle separately for the cleaning liquid and the rinse liquid may be also adopted.

In the case of supplying the rinse liquid, pure water may be also supplied from a nozzle for a back rinse that is not illustrated to the back of the substrate W so as to prevent the rinse liquid from flowing around to the back of the substrate W.

In the case of using pure water that cleans the substrate W, it is not necessary to supply the rinse liquid.

Although in the above-described embodiment, the substrate W is subjected to drying processing by a spin drying method, the substrate W may be also subjected to drying processing by other methods such as a reduced pressure drying method and an air knife drying method.

Although in the above-described embodiment, the inert gas is supplied from the nozzle 670 with the liquid layer L of the rinse liquid formed, the inert gas may be supplied from the nozzle 670 and the substrate W may be thoroughly dried immediately after the liquid layer of the cleaning liquid is shaken off once by rotating the substrate W when the liquid layer L of the rinse liquid is not formed or the rinse liquid is not used.

(5) Interface Transport Mechanism of the Interface Block

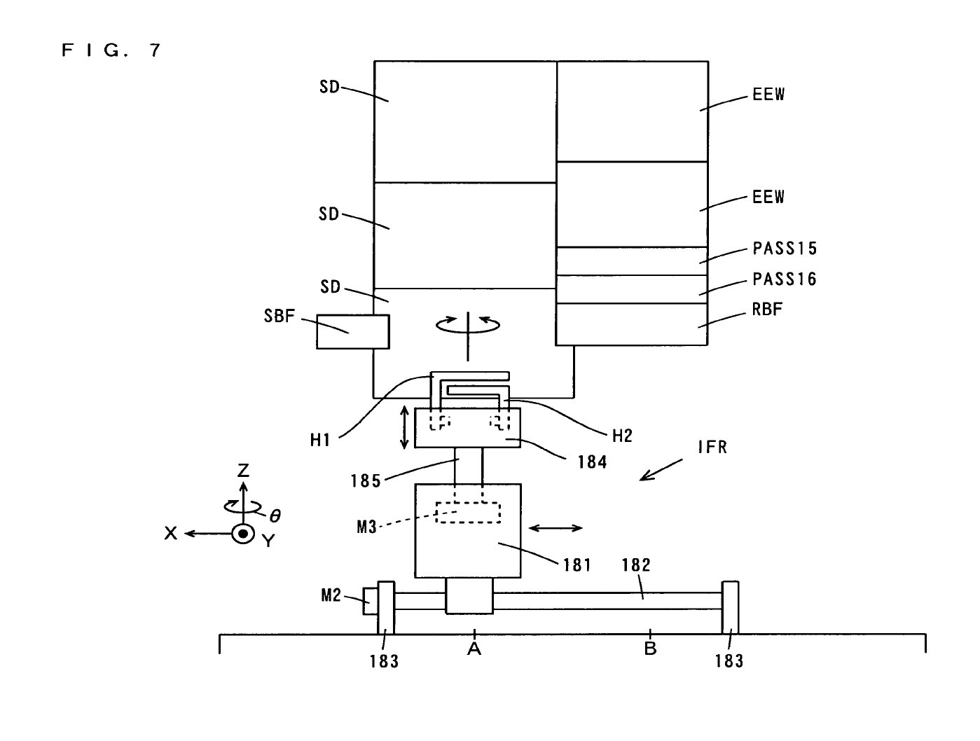

The interface transport mechanism IFR is described. FIG. 7 is a diagram for illustrating the configuration and the operation of the interface transport mechanism IFR.

The configuration of the interface transport mechanism IFR is first described. As shown in FIG. 7, a movable base 181 in the interface transport mechanism IFR is threadably mounted to a screwed shaft 182. The screwed shaft 182 is rotatably supported with support bases 183 so as to extend in the X direction. One end of the screwed shaft 182 is provided with a motor M2, which causes the screwed shaft 182 to rotate and the movable base 181 to move horizontally in the ±X direction.

Also, a hand support base 184 is mounted on the movable base 181 so as to rotate in the ±θ direction and move up and down in the ±Z direction. The hand support base 184 is coupled to a motor M3 in the movable base 181 through a rotation shaft 185 and rotated by the motor M3. Two hands H1, H2 for holding the substrate W in a horizontal attitude are provided to the hand support base 184 one above the other so as to move forward and backward.

The operation of the interface transport mechanism IFR is next described. The operation of the interface transport mechanism IFR is controlled by the main controller 91 in FIG. 1.

The interface transport mechanism IFR initially rotates the hand support base 184 at a position A in FIG. 7 while lifting the hand support base 184 in the +Z direction, to allow the upper hand H1 to enter the substrate platform PASS15. When the hand H1 has received the substrate W in the substrate platform PASS15, the interface transport mechanism IFR retracts the hand H1 from the substrate platform PASS15 and lowers the hand support base 184 in the −Z direction.

The interface transport mechanism IFR then moves in the −X direction, and rotates the hand support base 184 at a position B while allowing the hand H1 to enter the substrate inlet 17a in the exposure device 17 (see FIG. 1). After carrying the substrate W into the substrate inlet 17a, the interface transport mechanism IFR retracts the hand H1 from the substrate inlet 17a.

The interface transport mechanism IFR subsequently allows the lower hand H2 to enter the substrate outlet 17b (see FIG. 1). When the hand H2 has received the substrate W after the exposure processing from the substrate outlet 17b, the interface transport mechanism IFR retracts the hand H2 from the substrate outlet 17b.

After that, the interface transport mechanism IFR moves in the +X direction, and rotates the hand support base 184 at the position A, while allowing the hand H2 to enter the cleaning/drying processing unit SD, and transfers the substrate W to the cleaning/drying unit SD.

This causes the cleaning/drying processing unit SD to apply cleaning and drying processing to the substrate W after exposure processing.

Then, the interface transport mechanism IFR allows the upper hand H1 to enter the cleaning/drying unit SD, and receives the substrate W after cleaning and drying processing from the cleaning/drying processing unit SD. The substrate W is mounted onto the upper substrate platform PASS16 by the interface transport mechanism IFR.

As mentioned above, if the exposure device 17 is not capable of receiving the substrate W, the substrate W is temporarily stored at the sending buffer unit SBF. Also, if the cleaning/drying unit SD is not capable of performing cleaning and drying processing temporarily, the substrate W after the exposure processing is temporarily stored in the return buffer unit RBF in the interface block 15.

Although the single interface transport mechanism IFR transports the substrate W from the substrate platform PASS15 to the exposure device 17 and from the exposure device 17 to the cleaning/drying processing unit SD in this embodiment, a plurality of interface transport mechanisms IFR may be used for transporting the substrate W.

(6) Effects

(6-a) Effects of Hydrophobic Processing

As mentioned above, in the substrate processing apparatus 500 according to this embodiment, the hydrophobic processing is performed on the surface of the resist cover film on the substrate W by the hydrophobic processing unit HYP, thereby preventing liquid from soaking into the resist film and the resist cover film during the exposure processing in the exposure device 17. As a result, the generation of pattern defects is prevented in the process of post-exposure bake and development processing after exposure processing, so that the decrease in yield is suppressed.

(6-b) Effects of the Hydrophobic Processing Unit HYP

In the hydrophobic processing unit HYP according to this embodiment, the hydrophobic processing is performed on the surface of the resist cover film on the substrate W by supplying a vaporized hydrophobic material in the liquid storage tank 212 to the substrate W. Thus, the influence on the resist film and the resist cover film on the substrate W is reduced, as compared with that in a case of using a liquid hydrophobic material. This prevents the degradation in photosensitivity of the resist film and in function of avoiding elution of the resist cover film. The function of avoiding elution of the resist cover film is described below.

A vaporized hydrophobic material is supplied to the substrate W through a plurality of holes of the current plate 210 fixed to the supporting member 210. This causes the hydrophobic material to be dispersed uniformly on the resist cover film on the substrate W.

In addition, when the vaporized hydrophobic material is supplied to the substrate W, the carry-in/out opening 209 of a cover 206 is closed by a shutter 218 and the hydrophobic material in the cover 206 is exhausted by the exhausting device 211b. This prevents the hydrophobic material from leaking out from the hydrophobic processing unit HYP.

Also, the temperature of the substrate W during the hydrophobic processing is kept at 23° C. (room temperature) to 150° C. This ensures adhesion of the hydrophobic material to the surface of the resist cover film without degrading the optical sensitivity of the resist film.

(6-c) Effects of Cleaning Processing of the Substrate after Exposure Processing

After the exposure processing is applied to the substrate W in the exposure device 17, the cleaning processing to the substrate W is performed in the cleaning/drying processing group 80 of the cleaning/drying processing block 15. In this case, even if particles and the like in the atmosphere adheres to the substrate W to which a liquid adheres during the exposure processing, the attachment can be removed. This prevents contamination of the substrate W.

Also, the drying processing of the substrate W after the exposure processing is performed in the cleaning/drying processing group 80. This prevents the liquid adhering to the substrate W after the exposure processing from dropping in the substrate processing apparatus 500. As a result, this prevents operational troubles such as abnormalities in the electric system of the substrate processing apparatus 500.

Moreover, drying the substrate W after the exposure processing prevents particles and the like in the atmosphere from adhering to the substrate W after the exposure processing, thereby preventing the substrate W from being contaminated.

Since the substrate W to which a liquid adheres is prevented from being transported, it is possible to prevent the liquid adhering to the substrate W during the exposure processing from influencing the atmosphere in the substrate processing apparatus 500. This facilitates the adjustment of the temperature and humidity in the substrate processing apparatus 500.

Furthermore, since the liquid adhering to the substrate W during the exposure processing is prevented from adhering to the indexer robot IR and the central robots CR1 to CR7, the liquid is prevented from adhering to the substrate W before the exposure processing. This prevents particles and the like in the atmosphere from adhering to the substrate W before the exposure processing, thereby preventing the contamination of the substrate W. Consequently, this prevents degradation in the resolution performance during the exposure processing and ensures prevention of contamination in the exposure device 17.

As a result of the foregoing, prevention of processing defects in the substrate W can be ensured.

Note that the configuration for performing the drying processing on the substrate W after the exposure processing is not limited to the example of the substrate processing apparatus 500 in FIG. 1. Instead of providing the cleaning/drying processing block 15 between the resist cover film removal block 14 and the interface block 16, it may be possible to provide the cleaning/drying processing group 80 in the interface block 16 and apply the drying processing to the substrate W after the exposure processing.

(6-d) Effects of Drying Processing of the Substrate after Exposure Processing

The cleaning/drying processing unit SD applies the drying processing to the substrate W by spraying the inert gas onto the substrate W from the center to the peripheral portion thereof while rotating the substrate W. This ensures that the cleaning liquid and the rinse liquid are removed from the substrate W, which reliably prevents the attachment of particles and the like in the atmosphere on the cleaned substrate W. It is thus possible to reliably prevent the contamination of the substrate W and the generation of dry marks on the surface of the substrate W.

(6-e) Effects of the Cleaning/Drying Processing Block

Since the substrate processing apparatus 500 according to this embodiment has the configuration in which the cleaning/drying processing block 15 is added to an existing substrate processing apparatus, processing defects of the substrate W can be prevented at a lower cost.

(6-f) Effects of the Hands of Interface Transport Mechanism

When transporting the substrate W before exposure processing from the substrate platform PASS15 to the substrate inlet 17a of the exposure device 17 and when transporting the substrate W after cleaning and drying processing from the cleaning/drying processing unit SD to the substrate platform PASS16 in the interface block 16, the interface transport mechanism IFR employs the hand H1. When transporting the substrate W after exposure processing from the substrate outlet 17b of the exposure device 17 to the cleaning/drying processing unit SD, the interface transport mechanism IFR employs the hand H2.

This is, the hand H1 is used for transporting the substrate W to which no liquid adheres while the hand H2 is used for transporting the substrate W to which liquid adheres.

Since the liquid adhering to the substrate W during exposure processing is prevented from adhering to the hand H1, a liquid is prevented from adhering to the substrate W before exposure processing. Also, since the hand H2 is provided below the hand H1, a liquid is prevented from adhering to the hand H1 and the substrate W held thereby even if a liquid drops from the hand H2 and the substrate W held thereby. This can reliably prevent the liquid from adhering to the substrate W before the exposure processing. As a result, contamination of the substrate W before the exposure processing can be reliably prevented.

(6-g) Effects of Coating Processing of the Resist Cover Film

Before exposure processing is performed on the substrate W in the exposure device 17, the resist cover film is formed on the resist film in the resist cover processing block 13. In this case, even if the substrate W is brought into contact with a liquid in the exposure device 17, the resist cover film prevents the contact of the resist film with the liquid, which prevents a component from being eluted into the liquid.

(6-h) Effects of Removal Processing of the Resist Cover

Before development processing is applied to the substrate W in the development processing block 12, resist cover film removal processing is performed in the resist cover film removal block 14. In this case, the resist cover film is reliably removed before the development processing, which allows the development processing to be reliably performed.

(7) Other Effects

(7-a) Cleaning Processing of Substrates Before Exposure Processing

In the substrate processing apparatus 500 according to the embodiment, cleaning processing to the substrate W may be performed before exposure processing. In this case, cleaning and drying processing to the substrate W before the exposure processing are performed in the cleaning/drying processing group 80 in the cleaning/drying processing block 15, for example. This enables the removal of the particles and the like adhering to the substrate W before the exposure processing. Consequently, contamination in the exposure device 17 can be avoided.

Also, drying processing of the substrate W is performed in the cleaning/drying processing group 80 after the cleaning processing. This removes the cleaning liquid or the rinse liquid adhering to the substrate W during the cleaning processing, which prevents the particles and the like in the atmosphere from adhering to the substrate W after the cleaning processing again. As a result, contamination in the exposure device 17 can be reliably prevented.

Before the exposure processing is applied to the substrate W in the exposure device 17 after the formation of the resist cover film, the cleaning processing to the substrate W is performed in the cleaning/drying processing group 80. At this time, part of a component of the resist cover film formed on the substrate W is eluted into the cleaning liquid. Even if the substrate W is brought into contact with the liquid in the exposure device 17, the component of the resist cover film is prevented from being eluted into the liquid.

As a result of the foregoing, contamination in the exposure device 17 can be reliably prevented while the components of the resist film and the resist cover film are prevented from remaining on the surface of the substrate W. This surely prevents processing defects of the substrate W from being generated.

Moreover, cleaning and drying processing of the substrate W may be performed by providing the cleaning/drying processing group 80 in the interface block 16.

(7-b) Resist Cover Film Processing Block

In the case of performing cleaning processing to the substrate W before exposure processing, the resist cover film processing block 13 may not be provided. In this case, part of a component of the resist is eluted into the cleaning liquid during the cleaning processing in the cleaning/drying processing group 80 in which the cleaning processing to the substrate W is performed before the exposure processing. Even if the resist film is brought into contact with the liquid in the exposure device 17, the component of the resist is prevented from being eluted into the liquid. As a result, contamination in the exposure device 17 can be prevented.

In the case of applying cleaning processing to the substrate W before exposure processing, the resist cover film processing block 13 may not be provided. In this case, the resist cover film removal block 14 is not needed.

Furthermore, where the resist cover film processing block 13 is not provided, the hydrophobic processing unit HYP is provided in at least one of the resist film processing block 11 and the development processing block 12. In this case, hydrophobic processing is applied to the surface of the resist film on the substrate W by the hydrophobic processing unit HYP. This prevents a liquid from soaking into the resist during exposure processing in the exposure device 17.

These can reduce the footprint of the substrate processing apparatus 500.

Note that this embodiment describes the case where the film made of a hydrophobic material is not formed on the resist cover film when the hydrophobic processing is applied to the surface of the resist cover film on the substrate W by the hydrophobic processing unit HYP.

In the case where the film made of a hydrophobic material is formed on the resist cover film, the film made of the hydrophobic material and the resist cover film are removed simultaneously in the resist cover film removal processing group 70a or the resist cover film removal processing group 70b in the resist cover film removal block 14. This ensures the development processing after the exposure processing.

Also, in the case where the cleaning processing to the substrate W is performed before exposure processing and the resist cover film processing block 13 and the resist cover film removal block 14 are not provided, the hydrophobic processing is applied to the surface of the resist film on the substrate W. Where the film made of a hydrophobic material is formed on the resist film by the hydrophobic processing, the removal unit for the film made of the hydrophobic material may be provided in at least one of the cleaning/drying processing block 15 and the development processing block 12. This causes the removal processing of the film made of the hydrophobic material formed on the resist film of the substrate W to be performed, which ensures the development processing after the exposure processing.

(7-c) Effects of the Cleaning/Drying Processing Unit

As mentioned above, since the drying processing of the substrate W is performed by spraying the inert gas from the center of the substrate W to its peripheral portion while rotating the substrate W in the cleaning/drying processing unit SD, the cleaning liquid and the rinse liquid can be reliably removed.

This can reliably prevent the components of the resist film and the resist cover film from being eluted into the cleaning liquid and the rinse liquid remaining on the substrate W when the substrate W is transported from the cleaning/drying processing group 80 to the development processing group 50. This can prevent the deformation of exposure patterns formed on the resist film. As a result, degradation in accuracy of line-width during the development processing is reliably prevented.

(7-d) Water-Resistant Substrate Processing Apparatus

If the substrate processing apparatus 500 has sufficient waterproofing function, the cleaning/drying processing group 80 may not be provided. This causes the footprint of the substrate processing apparatus 500 to be reduced. Also, since transporting the substrate W to the cleaning/drying processing group 80 after the exposure processing is omitted, the productivity of the substrate W is improved.

(7-e) Effects of Hands of Robots

In the first to fifth central robots CR1-CR5 and the indexer robot IR, the upper hand is used for transporting the substrate W before the exposure processing while the lower hand is used for transporting the substrate W after the exposure processing. This can reliably prevent a liquid from adhering to the substrate W before the exposure processing.

(8) Other Examples of the Cleaning/Drying Processing Unit

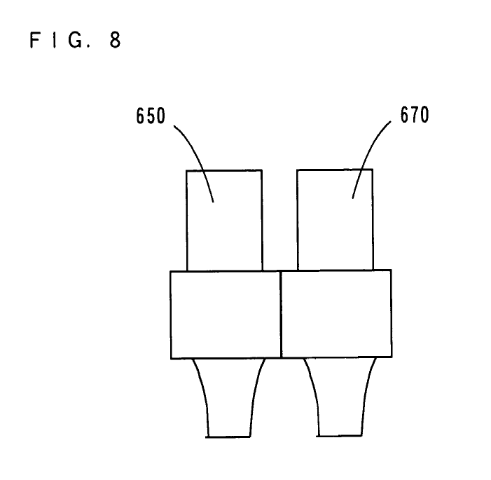

Moreover, although the cleaning/drying processing unit SD shown in FIG. 5 includes the nozzle 650 for cleaning processing and the nozzle 670 for drying processing separately, the nozzle 650 and the nozzle 670 may also be formed integrally, as shown in FIG. 8. This obviates the need to move each of the nozzle 650 and the nozzle 670 separately during the cleaning and drying processing to the substrate W, thereby simplifying the driving mechanism.

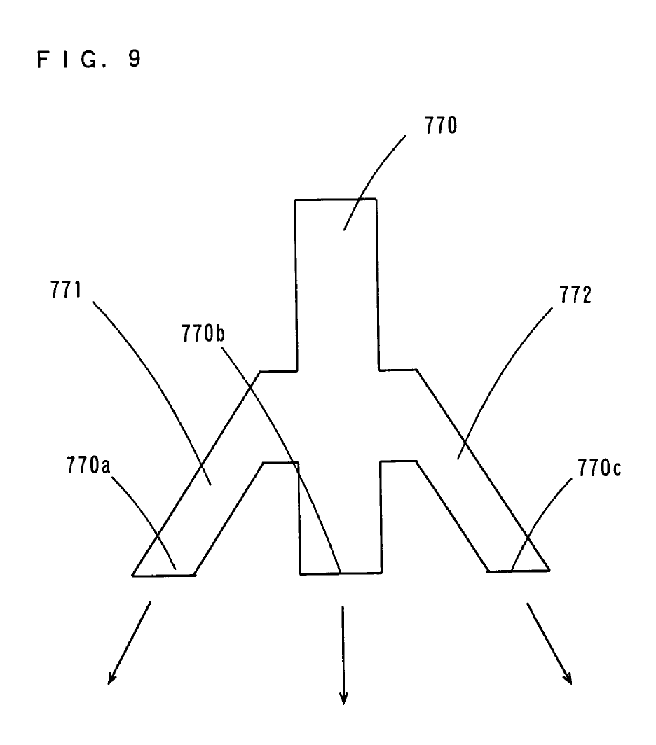

A nozzle 770 for drying processing shown in FIG. 9 may be used instead of the nozzle 670 for drying processing shown in FIG. 5.

The nozzle 770 shown in FIG. 9 extends vertically downward and also has branch pipes 771, 772 that extend obliquely downward from the sides thereof. A gas discharge port 770a is formed at the lower end of the branch pipe 771, a gas discharge port 770b at the lower end of the nozzle 770, and a gas discharge port 770c at the lower end of the branch pipe 772, each for discharging an inert gas. The discharge port 770b discharges an inert gas vertically downward, and the discharge ports 770a, 770c each discharge an inert gas obliquely downward, as indicated by the arrows in FIG. 9. That is to say, the nozzle 770 discharges the inert gas so as to increase the spraying area downwardly.

Now, a cleaning/drying processing unit SD using the nozzle 770 for drying processing applies drying processing to the substrate W as will be described below.

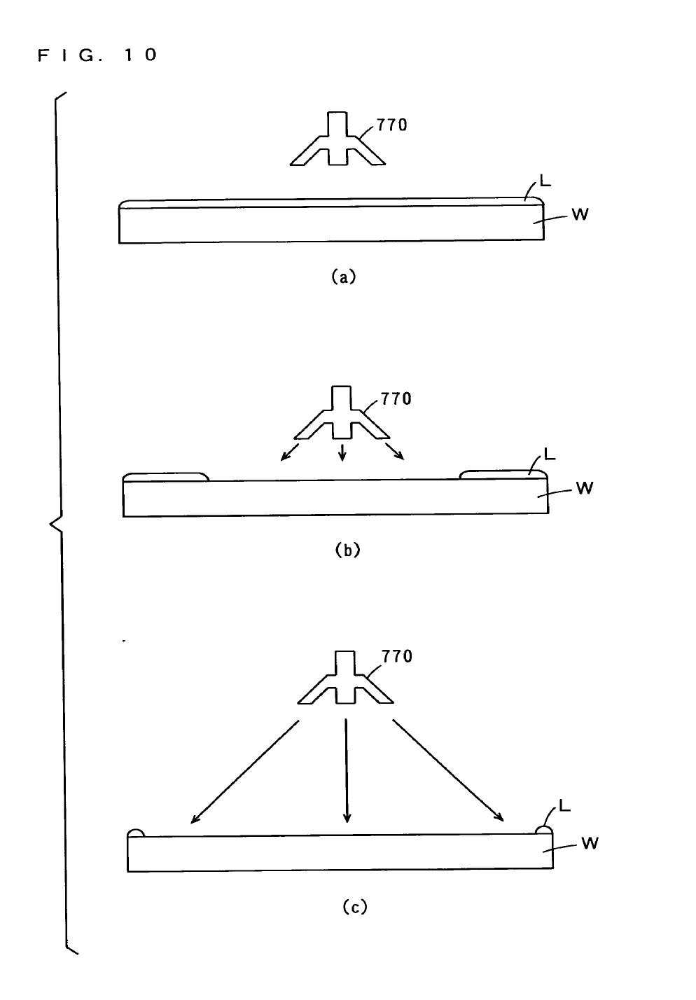

FIG. 10 is a diagram for use in illustrating a method of applying drying processing to the substrate W using the nozzle 770.

Initially, a liquid layer L is formed on a surface of the substrate W by the method as described in FIG. 6, and then the nozzle 770 moves above the center of the substrate W, as shown in FIG. 10(a). After this, an inert gas is discharged from the nozzle 770. This causes the rinse liquid on the center of the substrate W to move to the peripheral portion of the substrate W, leaving the liquid layer L only on the peripheral portion of the substrate W, as shown in FIG. 10 (b). At the time, the nozzle 770 is brought close to the surface of the substrate W so as to reliably move the rinse liquid present on the center of the substrate W.

Next, as the number of revolutions of the rotation shaft 625 (see FIG. 5) increases, the nozzle 770 moves upward as shown in FIG. 10(c). This causes a great centrifugal force acting on the liquid layer L on the substrate W while increasing the area to which the inert gas is sprayed on the substrate W. As a result, the liquid layer L on the substrate W can be reliably removed. Note that the nozzle 770 can be moved up and down by lifting and lowering the second rotation shaft 672 via a rotation shaft lifting mechanism (not shown) provided to the second rotation shaft 672 in FIG. 5.

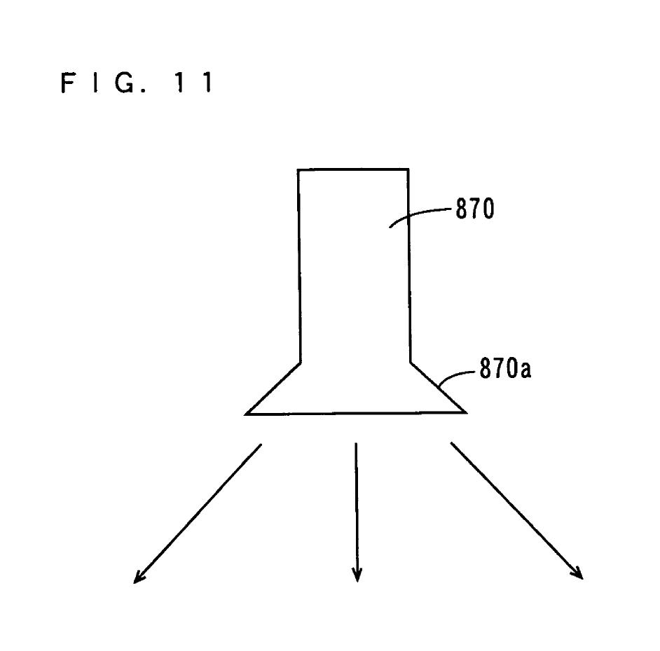

Alternatively, a nozzle 870 for drying processing as shown in FIG. 11 may be used instead of the nozzle 770. The nozzle 870 in FIG. 11 has a discharge port 870a whose diameter gradually increases downward. This discharge port 870a discharges an inert gas vertically downward and obliquely downward as indicated by the arrows in FIG. 11. That is, similarly to the nozzle 770 in FIG. 9, the nozzle 870 discharges the inert gas so as to increase the spraying area downwardly. Consequently, drying processing similar to that using the nozzle 770 can be applied to the substrate W using the nozzle 870.

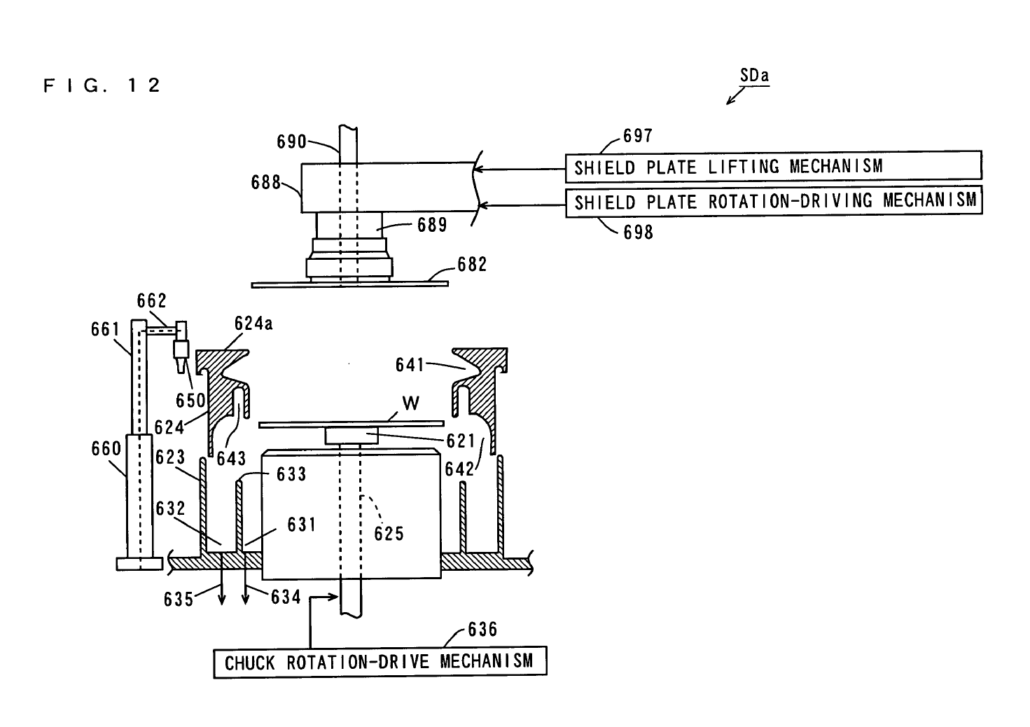

A cleaning/drying processing unit SDa as shown in FIG. 12 may also be used instead of the cleaning/drying processing unit SD shown in FIG. 5.

The cleaning/drying processing unit SDa in FIG. 12 is different from the cleaning/drying processing unit SD in FIG. 5 as described below.

The cleaning/drying processing unit SDa in FIG. 12 includes above the spin chuck 621 a disk-shaped shield plate 682 having an opening through the center thereof. A support shaft 689 extends vertically downward from around an end of an arm 688, and the shield plate 682 is mounted at a lower end of the support shaft 689 so as to oppose the top surface of the substrate W held on the spin chuck 621.

A gas supply passage 690 that communicates with the opening of the shield plate 682 is inserted into the inside of the support shaft 689. A nitrogen gas (N₂), for example, is supplied into the gas supply passage 690.

The arm 688 is connected with a shield plate lifting mechanism 697 and a shield plate rotation-driving mechanism 698. The shield plate lifting mechanism 697 lifts and lowers the shield plate 682 between a position close to the top surface of the substrate W held on the spin chuck 621 and a position upwardly away from the spin chuck 621.

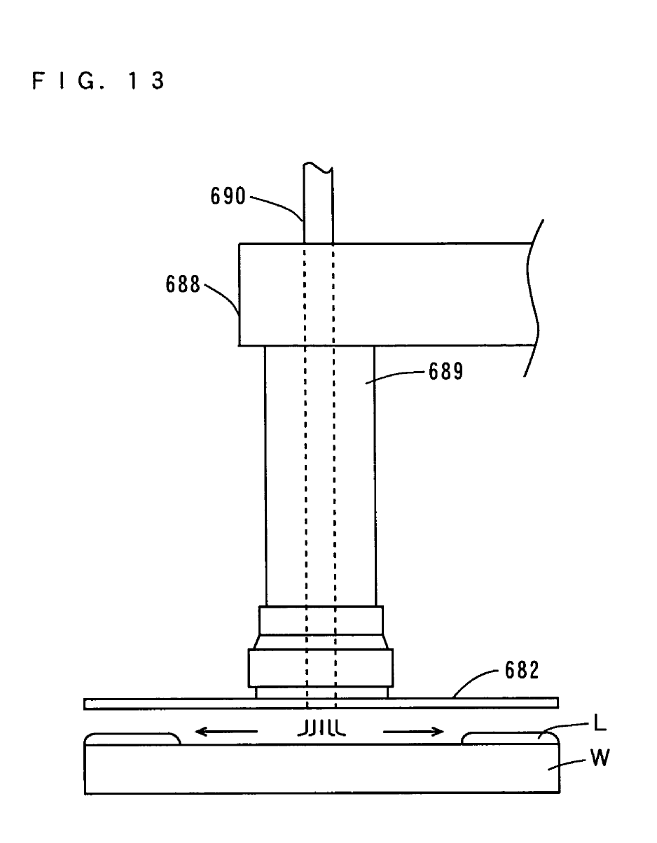

During the drying processing to the substrate W in the cleaning/drying processing unit SDa in FIG. 12, with the shield plate 682 brought close to the substrate W as shown in FIG. 13, an inert gas is supplied to clearance between the substrate W and the shield plate 682 from the gas supply passage 690. This allows the inert gas to be efficiently supplied from the center of the substrate W to the peripheral portion thereof, thereby ensuring the removal of the liquid layer L on the substrate W.

(Correspondence Between Each Constituent Element of the Claims and Each Part of the Embodiment)

According to the above embodiment, the interface block 16 corresponds to the interface; the resist film corresponds to the photosensitive film; the coating unit RES corresponds to the photosensitive film formation unit; the hydrophobic processing unit HYP corresponds to the hydrophobic processing unit; the vaporization processing device 201 corresponds to the vaporizer; the hydrophobic material supply device 202 corresponds to the hydrophobic material supply device; the substrate platform plate 203 corresponds to the thermal control device; the resist cover film corresponds to the protective film; the coating unit COV corresponds to the protective film formation unit; the removal unit REM corresponds to the removal unit and the coating unit BARC corresponds to the anti-reflection film formation unit.

While preferred embodiments of the present invention have been described above, it is to be understood that variations and modifications will be apparent to those skilled in the art without departing the scope and spirit of the present invention. The scope of the present invention, therefore, is to be determined solely by the following claims.

What is claimed is:

1. A substrate processing method of processing a substrate using a substrate processing apparatus that is arranged adjacent to an exposure device, comprising the steps of:
forming a photosensitive film made of a photosensitive material on the substrate by said substrate processing apparatus;
applying hydrophobic processing to the substrate after formation of said photosensitive film by said substrate processing apparatus;
carrying the substrate after the hydrophobic processing from said substrate processing apparatus into said exposure device;
carrying the substrate after exposure processing by said exposure device out of said exposure device to said substrate processing apparatus; and
applying processing after the exposure processing to the substrate by said substrate processing apparatus.

2. The substrate processing method according to claim 1, wherein said step of applying the hydrophobic processing includes the step of supplying a hydrophobic material to the substrate.

3. The substrate processing method according to claim 2, wherein said step of supplying said hydrophobic material to the substrate includes the step of supplying said hydrophobic material to the substrate in a gaseous state.

4. The substrate processing method according to claim 3, wherein said step of supplying said hydrophobic material to the substrate in the gaseous state includes supplying said hydrophobic material to the substrate through a plurality of holes of a current plate having said plurality of holes.

5. The substrate processing method according to claim 1, wherein said step of applying the hydrophobic processing includes the step of controlling the temperature of the substrate.

6. The substrate processing method according to claim 5, wherein said step of controlling the temperature of the substrate includes controlling the temperature of the substrate within the range of 23 to 150° C.

7. The substrate processing method according to claim 1 wherein said step of applying the hydrophobic processing includes applying hydrophobic processing to said photosensitive film formed on the substrate.

8. The substrate processing method according to claim 1, further comprising the step of forming a protective film for protecting said photosensitive film on the substrate by said substrate processing apparatus, wherein said step of applying to the hydrophobic processing includes applying hydrophobic processing to said protective film formed on the substrate.

9. The substrate processing method according to claim 8, wherein said step of applying processing after the exposure processing includes removing said protective film.

10. The substrate processing method according to claim 1, wherein
said step of applying processing after the exposure processing includes applying drying processing to the substrate by using a drying processing unit provided in said substrate processing apparatus, and
said step of carrying out includes transporting the substrate after the exposure processing from said exposure device to said drying processing unit by a transport unit provided in said substrate processing apparatus.

11. The substrate processing method according to claim 10, wherein
said step of carrying in includes transporting the substrate from said substrate processing apparatus to said exposure device by a first holder provided in said transport unit, and
said step of carrying out includes transporting the substrate after the exposure processing from said exposure device to said drying processing unit by a second holder provided in said transport unit,
said substrate processing method further comprising the step of transporting the substrate after the drying processing by said drying processing unit by using said first holder of said transport unit.

12. The substrate processing method according to claim 11, wherein said second holder is provided below said first holder.

13. The substrate processing method according to claim 1, wherein said step of applying the processing after the exposure processing includes applying development processing to the substrate.

14. The substrate processing method according to claim 1, further comprising the step of forming an anti-reflection film on the substrate before forming said photosensitive film by said substrate processing apparatus.
